(19) United States
(12) Patent Application Publication
(10) Pub. No.: US 2025/0365857 A1
(43) Pub. Date: Nov. 27, 2025

(54) MULTILAYER SUBSTRATE, ELECTRONIC DEVICE, AND METHOD FOR MANUFACTURING MULTILAYER SUBSTRATE

(71) Applicant: Murata Manufacturing Co., Ltd., Nagaokakyo-shi (JP)

(72) Inventors: Nobuo IKEMOTO, Nagaokakyo-shi (JP); Masanori OKAMOTO, Nagaokakyo-shi (JP); Yasushi OYAMA, Nagaokakyo-shi (JP)

(21) Appl. No.: 19/294,739

(22) Filed: Aug. 8, 2025

Related U.S. Application Data
(63) Continuation of application No. PCT/JP2024/000392, filed on Jan. 11, 2024.

(30) Foreign Application Priority Data
Feb. 16, 2023 (JP) 2023-022143

(51) Int. Cl. H05K 1/02; H05K 1/11; H05K 3/40

(52) U.S. Cl. CPC H05K 1/024; H05K 1/115; H05K 3/4038; H05K 2201/09827

(57) ABSTRACT

A multilayer substrate includes a first insulator layer including a first through-hole penetrating the first insulator layer along a Z-axis, a second insulator layer including a second through-hole penetrating the second insulator layer along the Z-axis. The second through-hole overlaps the first through-hole when viewed downward. When viewed in a positive direction of the Z-axis, an area of an end portion of the second through-hole on a positive side of the Z-axis is larger than an area of an end portion of the first through-hole on a negative side of the Z-axis. A first interlayer connection conductor extends along the Z-axis inside the first through-hole and the second through-hole and electrically connects first and second conductor layers. A space exists between a boundary of the first insulator layer and the second insulator layer and the first interlayer connection conductor.

### CROSS REFERENCE TO RELATED APPLICATIONS

This application claims the benefit of priority to Japanese Patent Application No. 2023-022143 filed on Feb. 16, 2023 and is a Continuation application of PCT Application No. PCT/JP2024/000392 filed on Jan. 11, 2024. The entire contents of each application are hereby incorporated herein by reference.

### BACKGROUND OF THE INVENTION

### 1. Field of the Invention

The present invention relates to multilayer substrates each including a plurality of insulator layers that are laminated.

### 2. Description of the Related Art

A signal transmission line described in Japanese Patent No. 7205667 is known, for example, as an invention relating to a multilayer substrate of the related art. This signal transmission line includes an interlayer connection conductor.

In the field of the signal transmission line described in Japanese Patent No. 7205667, there is a demand for reducing damage to the interlayer connection conductor.

### SUMMARY OF THE INVENTION

Example embodiments of the present invention provide multilayer substrates, electronic devices, and methods for manufacturing multilayer substrates, which are each able to reduce or prevent damage to an interlayer connection conductor.

A multilayer substrate according to an example embodiment of the present invention includes a multilayer body, a first conductor layer, a second conductor layer, and a first interlayer connection conductor. The multilayer body includes a plurality of insulator layers including a first insulator layer and a second insulator layer laminated along a Z-axis. The first insulator layer and the second insulator layer each include a positive main surface and a negative main surface. The positive main surface of the second insulator layer is in contact with the negative main surface of the first insulator layer. The first conductor layer is located on a positive side of the Z-axis relative to the first insulator layer. The second conductor layer is located on a negative side of the Z-axis relative to the second insulator layer. The first insulator layer includes a first through-hole penetrating the first insulator layer along the Z-axis. The second insulator layer includes a second through-hole penetrating the second insulator layer along the Z-axis. The second through-hole overlaps the first through-hole when viewed downward. When viewed in a positive direction of the Z-axis, an area of an end portion of the second through-hole on the positive side of the Z-axis is larger than an area of an end portion of the first through-hole on the negative side of the Z-axis. The first interlayer connection conductor extends along the Z-axis inside the first through-hole and the second through-hole and electrically connects the first conductor layer and the second conductor layer. A space exists between a boundary of the first insulator layer and the second insulator layer and the first interlayer connection conductor.

A method for manufacturing a multilayer substrate according to an example embodiment of the present invention includes preparing a first insulator layer and a second insulator layer, each including a positive main surface and a negative main surface aligned along a Z-axis, forming a first through-hole penetrating the first insulator layer along the Z-axis, forming a second through-hole penetrating the second insulator layer along the Z-axis, and laminating the first insulator layer and the second insulator layer so that the negative main surface of the first insulator layer is in contact with the positive main surface of the second insulator layer, and forming a first interlayer connection conductor extending along the Z-axis inside the first through-hole and the second through-hole. When viewed in a positive direction of the Z-axis, an area of an end portion of the second through-hole on a positive side of the Z-axis is larger than an area of an end portion of the first through-hole on a negative side of the Z-axis. A space exists between a boundary of the first insulator layer and the second insulator layer and the first interlayer connection conductor. The space faces at least a portion of an inner circumferential surface of the first through-hole and faces at least a portion of an inner circumferential surface of the second through-hole.

Multilayer substrates and methods for manufacturing multilayer substrates according to example embodiments of the present invention are each able to reduce or prevent damage to an interlayer connection conductor.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is an exploded perspective view of a multilayer substrate 10 according to an example embodiment of the present invention.

FIG. 2 is a sectional view of the multilayer substrate 10.

FIG. 3 is a sectional view of the multilayer substrate 10.

FIG. 4 is a sectional view of the multilayer substrate 10 during manufacture.

FIG. 5 is a sectional view of a multilayer substrate 10a according to an example embodiment of the present invention.

FIG. 6 is a sectional view of a multilayer substrate 10b according to an example embodiment of the present invention.

FIG. 7 is a sectional view of a multilayer substrate 10c according to an example embodiment of the present invention.

FIG. 8 is a sectional view of a multilayer substrate 10d according to an example embodiment of the present invention.

FIG. 9 is a sectional view of a multilayer substrate 10e according to an example embodiment of the present invention.

FIG. 10 is a sectional view of a multilayer substrate 10f according to an example embodiment of the present invention.

FIG. 11 is a sectional view of a multilayer substrate 10g according to an example embodiment of the present invention.

FIG. 12 is a sectional view of a multilayer substrate 10h according to an example embodiment of the present invention.

FIG. 13 is a sectional view of a multilayer substrate 10i according to an example embodiment of the present invention.

FIG. 14 is a sectional view of a multilayer substrate 10j according to an example embodiment of the present invention.

FIG. 15 is a sectional view of a first interlayer connection conductor v3a and the vicinity thereof in a multilayer substrate 10k.

FIG. 16 is a sectional view of a first interlayer connection conductor v3a and the vicinity thereof in a multilayer substrate 10l.

FIG. 17 is a sectional view of a first interlayer connection conductor v3a and the vicinity thereof in a multilayer substrate 10m.

FIG. 18 is a sectional view of a first interlayer connection conductor v3a and the vicinity thereof in a multilayer substrate 10n according to an example embodiment of the present invention.

FIG. 19 is a sectional view of a multilayer substrate 10o according to an example embodiment of the present invention.

FIG. 20 is a sectional view of a multilayer substrate 10p according to an example embodiment of the present invention.

FIG. 21 is a sectional view of an electronic device 1 including the multilayer substrate 10 according to an example embodiment of the present invention.

### DETAILED DESCRIPTION OF THE EXAMPLE EMBODIMENTS

Example embodiments of the present invention will be described below with reference to the drawings.

### EXAMPLE EMBODIMENTS

### Structure of Multilayer Substrate

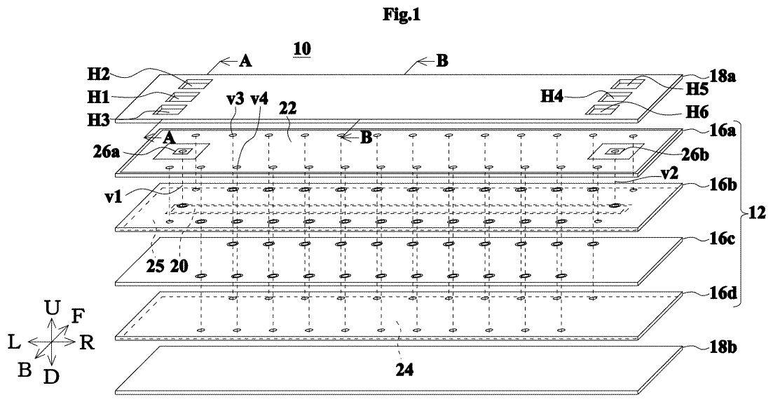

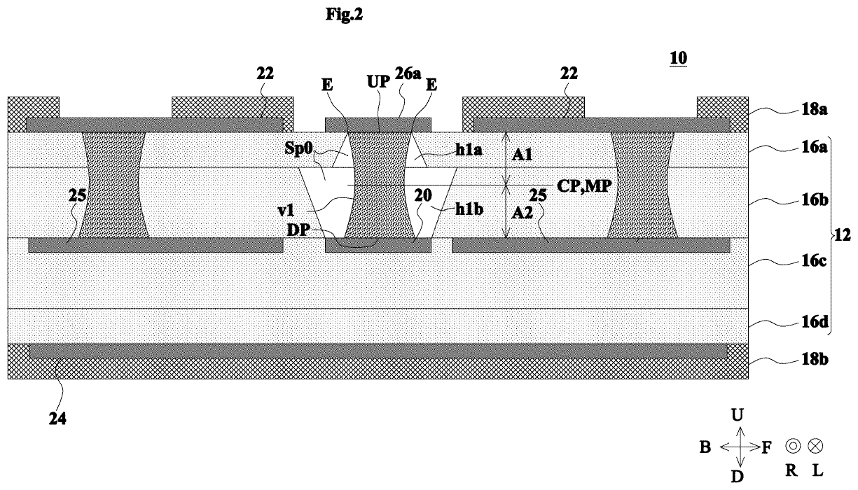

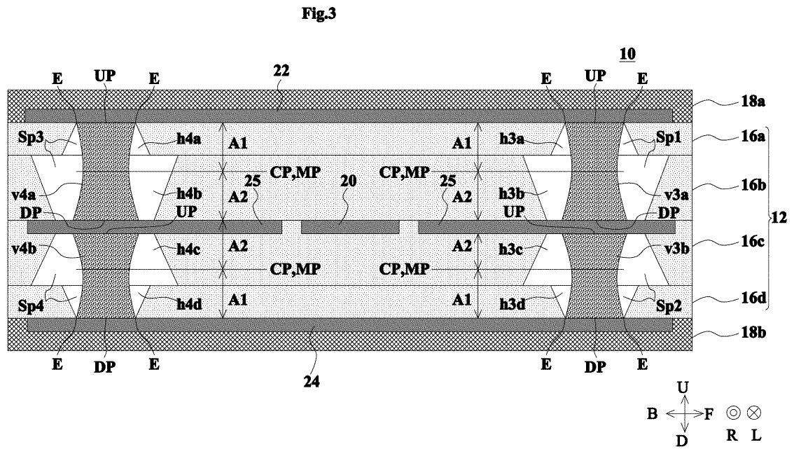

A structure of a multilayer substrate 10 according to an example embodiment of the present invention will be described below with reference to the drawings. FIG. 1 is an exploded perspective view of the multilayer substrate 10. FIGS. 2 and 3 are sectional views of the multilayer substrate 10. FIG. 2 shows a cross section taken along line A-A in FIG. 1. FIG. 3 shows a cross section taken along line B-B in FIG. 1. In FIG. 1, only representative first interlayer connection conductors v3 and v4 among pluralities of first interlayer connection conductors v3 and v4 are denoted by reference numerals.

In this specification, directions are defined as follows. A lamination direction of a multilayer body 12 of the multilayer substrate 10 is parallel or substantially parallel to an up-down axis. The up-down axis coincides with a Z-axis. An upward direction is the positive direction of the Z-axis. A downward direction is the negative direction of the Z-axis. An extending direction of a signal conductor layer 20 of the multilayer substrate 10 is parallel or substantially parallel to a left-right axis. A line width direction of the signal conductor layer 20 when viewed downward is parallel or substantially parallel to a front-back axis. The up-down axis, the front-back axis, and the left-right axis are orthogonal or substantially orthogonal to each other. It is not necessary that the up-down axis, the left-right axis, and the front-back axis coincide with the up-down axis, the left-right axis, and the front-back axis, respectively, when the multilayer substrate 10 is in use.

Hereinafter, X is a component or element of the multilayer substrate 10. In this specification, unless otherwise specified, each portion of X is defined as follows. The front portion of X means the front half of X. The rear portion of X means the rear half of X. The left portion of X means the left half of X. The right portion of X means the right half of X. The upper portion of X means the upper half of X. The lower portion of X means the lower half of X. The front end of X means the forward end of X. The rear end of X means the rearward end of X. The left end of X means the leftward end of X. The right end of X means the rightward end of X. The upper end of X means the upward end of X. The lower end of X means the downward end of X. The front end portion of X means the front end of X and its vicinity. The rear end portion of X means the rear end of X and its vicinity. The left end portion of X means the left end of X and its vicinity. The right end portion of X means the right end of X and its vicinity. The upper end portion of X means the upper end of X and its vicinity. The lower end portion of X means the lower end of X and its vicinity.

First, the structure of the multilayer substrate 10 will be described with reference to FIG. 1. The multilayer substrate 10 transmits high-frequency signals. The multilayer substrate 10 is used to electrically connect two circuits in an electronic device such as a smartphone, for example. As shown in FIG. 1, the multilayer substrate 10 includes the multilayer body 12, protective layers 18a and 18b, a signal conductor layer 20, a first ground conductor layer 22 (first conductor layer), a second ground conductor layer 24, a third ground conductor layer 25 (second conductor layer), mounting electrodes 26a and 26b, first interlayer connection conductors v1 and v2, the plurality of first interlayer connection conductors v3, and the plurality of first interlayer connection conductors v4.

The multilayer body 12 has a plate shape. Therefore, the multilayer body 12 includes an upper main surface and a lower main surface located below the upper main surface. The upper main surface and the lower main surface of the multilayer body 12 have a rectangular or substantially rectangular shape with long sides extending along the left-right axis. Therefore, the length of the multilayer body 12 on the left-right axis is longer than the length of the multilayer body 12 on the front-back axis. The multilayer body 12 is flexible.

As shown in FIG. 1, the multilayer body 12 has a structure in which a plurality of insulator layers 16a to 16d, including an insulator layer 16a (first insulator layer) and an insulator layer 16b (second insulator layer), are laminated along the up-down axis (Z-axis). The insulator layers 16a to 16d each include an upper main surface (positive main surface) and a lower main surface (negative main surface). The insulator layers 16a to 16d are arranged in this order from top to bottom. As a result, the upper main surface (positive main surface) of the insulator layer 16b (second insulator layer) is in contact with the negative main surface of the insulator layer 16a (first insulator layer). The lower main surface of the insulator layer 16c is in contact with the upper main surface of the insulator layer 16d. The insulator layers 16a to 16d are made of, for example, a thermoplastic resin. The thermoplastic resin is, for example, a liquid crystal polymer. Thus, the material of the insulator layers 16a to 16d (the material of the first insulator layer and the second insulator layer) is a flexible resin. As for the insulator layers 16a to 16d, those adjacent to each other in the up-down direction are fused to each other. That is, the insulator layer 16a (first insulator layer) and the insulator layer 16b (second insulator layer) are fused to each other. The insulator layer 16c and the insulator layer 16d are fused to each other.

A high-frequency signal is transmitted to the signal conductor layer 20. The signal conductor layer 20 is provided in the multilayer body 12 as shown in FIG. 1. The signal conductor layer 20 is located on the lower main surface of the insulator layer 16b as shown in FIG. 1. The signal conductor layer 20 has a linear shape extending along the left-right axis.

The first ground conductor layer 22 is provided in the multilayer body 12 as shown in FIG. 1. The first ground conductor layer 22 is located above the signal conductor layer 20 and overlaps the signal conductor layer 20 when viewed downward. In the present example embodiment, the first ground conductor layer 22 is located on the upper main surface of the insulator layer 16a. As a result, the first ground conductor layer 22 (first conductor layer) is located on an upper side (on the positive side of the Z-axis) of the insulator layer 16a (first insulator layer). The first ground conductor layer 22 covers the entire or substantially the entire upper main surface of the insulator layer 16a. A ground potential is connected to the first ground conductor layer 22.

The second ground conductor layer 24 is provided in the multilayer body 12 as shown in FIG. 1. The second ground conductor layer 24 is located below the signal conductor layer 20 and overlaps the signal conductor layer 20 when viewed downward. In the present example embodiment, the second ground conductor layer 24 is located on the lower main surface of the insulator layer 16d. As a result, the second ground conductor layer 24 is located on the lower side of the insulator layer 16d. The second ground conductor layer 24 covers the entire or substantially the entire lower main surface of the insulator layer 16d. A ground potential is connected to the second ground conductor layer 24. The signal conductor layer 20, the first ground conductor layer 22, and the second ground conductor layer 24 as described above have a stripline structure.

The third ground conductor layer 25 is provided in the multilayer body 12 as shown in FIG. 1. The third ground conductor layer 25 is located below the first ground conductor layer 22 and above the second ground conductor layer 24. In the present example embodiment, the third ground conductor layer 25 is located on the lower main surface of the insulator layer 16b. As a result, the third ground conductor layer 25 (second conductor layer) is located on a lower side (on the negative side of the Z-axis) of the insulator layer 16b (second insulator layer). The third ground conductor layer 25 covers the entire or substantially the entire lower main surface of the insulator layer 16b. However, the third ground conductor layer 25 is not in contact with the signal conductor layer 20. Therefore, a cavity is provided in the third ground conductor layer 25. The signal conductor layer 20 is located inside the cavity. A ground potential is connected to the third ground conductor layer 25.

The mounting electrode 26a is provided on the multilayer body 12 as shown in FIG. 1. The mounting electrode 26a is located on the upper main surface of the multilayer body 12. More specifically, the mounting electrode 26a is located on the left end portion of the upper main surface of the insulator layer 16a. The mounting electrode 26a overlaps the left end portion of the signal conductor layer 20 when viewed downward. The mounting electrode 26a has a rectangular or substantially rectangular shape when viewed downward. The mounting electrode 26a is an external terminal through which the high-frequency signal is inputted and outputted. The mounting electrode 26a is not in contact with the first ground conductor layer 22. The mounting electrode 26b has a structure left-right symmetrical to that of the mounting electrode 26a, and thus description thereof will be omitted.

The first interlayer connection conductor v1 is provided in the multilayer body 12 as shown in FIG. 1. As shown in FIGS. 1 and 2, the first interlayer connection conductor v1 electrically connects the mounting electrode 26a and the left end portion of the signal conductor layer 20. More specifically, the insulator layer 16a (first insulator layer) is provided with a first through-hole h1a that penetrates the insulator layer 16a (first insulator layer) along the up-down axis (Z-axis). The first through-hole h1a has a tapered shape that becomes narrower in the upward direction (positive direction of the Z-axis). Therefore, the upper end portion of the first through-hole h1a is narrower than the lower end portion of the first through-hole h1a.

The insulator layer 16b (second insulator layer) is provided with a plurality of second through-holes h1b that penetrate the insulator layer 16b (second insulator layer) along the up-down axis (Z-axis). The second through-hole h1b has a tapered shape that becomes narrower in the downward direction (negative direction of the Z-axis). Therefore, the lower end portion of the second through-hole h1b is narrower than the upper end portion of the second through-hole h1b.

The second through-hole h1b overlaps the first through-hole h1a when viewed downward. When viewed upward (positive direction of the Z-axis), the area of the upper end portion (end portion on the positive side of the Z-axis) of the second through-hole h1b is larger than the area of the lower end portion (end portion on the negative side of the Z-axis) of the first through-hole h1a. As a result, when viewed upward (positive direction of the Z-axis), the lower end portion (end portion on the negative side of the Z-axis) of the first through-hole h1a fits into the upper end portion (end portion on the positive side of the Z-axis) of the second through-hole h1b. Specifically, when viewed upward, the lower end portion of the first through-hole h1a does not protrude from the upper end portion of the second through-hole h1b. The second through-hole h1b is thus connected to the first through-hole h1a.

The first interlayer connection conductor v1 extends along the up-down axis (Z-axis) within the first through-hole h1a and the second through-hole h1b. An upper end portion UP of the first interlayer connection conductor v1 is in contact with the mounting electrode 26a. A lower end portion DP of the first interlayer connection conductor v1 is in contact with the left end portion of the signal conductor layer 20. The first interlayer connection conductor v1 includes a middle portion MP located between the upper end portion UP (end portion on the positive side of the Z-axis) of the first interlayer connection conductor v1 and the lower end portion DP (end portion on the negative side of the Z-axis) of the first interlayer connection conductor v1. The middle portion MP is located at the same or substantially the same position as the center CP of the first interlayer connection conductor v1 on the up-down axis (Z-axis). However, the middle portion MP does not have to coincide with the center CP. The first interlayer connection conductor v1 includes a first section A1 having a tapered shape that becomes narrower from the upper end portion UP (end portion on the positive side of the Z-axis) toward the middle portion MP, and a second section A2 having a tapered shape that becomes narrower from the lower end portion DP (end portion on the negative side of the Z-axis) toward the middle portion MP.

A space Sp0 exists between the boundary of the insulator layer 16a (first insulator layer) and the insulator layer 16b (second insulator layer) and the first interlayer connection conductor v1. The space Sp0 also exists between the inner circumferential surface of the second through-hole h1b and the center CP of the first interlayer connection conductor v1 on the up-down axis (Z-axis). The space Sp0 faces at least a portion of the inner circumferential surface of the first through-hole h1a and faces at least a portion of the inner circumferential surface of the second through-hole h1b. In the present example embodiment, the space Sp0 faces the entire or substantially the entire inner circumferential surface of the first through-hole h1a and the entire or substantially the entire inner circumferential surface of the second through-hole h1b. Therefore, the first interlayer connection conductor v1 is in contact only with the upper end of the inner circumferential surface of the first through-hole h1a and the lower end of the inner circumferential surface of the second through-hole h1b, and is not in contact with any portion of the inner circumferential surface of the first through-hole h1a other than the upper end, nor with any portion of the inner circumferential surface of the second through-hole h1b other than the lower end. Therefore, the space Sp0 causes the first interlayer connection conductor v1 not to come into contact with the boundary between the insulator layer 16a (first insulator layer) and the insulator layer 16b (second insulator layer).

When viewed downward (in the negative direction of the Z-axis), at least a portion of the side surface of the first interlayer connection conductor v1 in the first section A1, at least a portion of the side surface of the first interlayer connection conductor v1 in the second section A2, and at least a portion of the space Sp0 overlap each other. This causes a portion of the space Sp0 to be located between the side surface of the first interlayer connection conductor v1 in the first section A1 and the side surface of the first interlayer connection conductor v1 in the second section A2.

The mounting electrode 26b and the first interlayer connection conductor v2 have a structure left-right symmetrical to that of the mounting electrode 26a and the first interlayer connection conductor v1, and thus description thereof will be omitted. A high-frequency signal having a frequency of, for example, about 1 GHz to about 1 THz is transmitted to the mounting electrodes 26a and 26b (first conductor layer), the signal conductor layer 20 (second conductor layer), and the first interlayer connection conductors v1 and v2 as described above.

As shown in FIG. 3, the plurality of first interlayer connection conductors v3 each include first interlayer connection conductors v3a and v3b. The plurality of first interlayer connection conductors v3a each electrically connect the first ground conductor layer 22 (first conductor layer) and the third ground conductor layer 25 (second conductor layer). More specifically, the insulator layer 16a (first insulator layer) is provided with a plurality of first through-holes h3a that penetrate the insulator layer 16a (first insulator layer) along the up-down axis (Z-axis). The plurality of first through-holes h3a each have a tapered shape that becomes narrower in the upward direction (positive direction of the Z-axis). Therefore, the upper end portion of the first through-hole h3a is narrower than the lower end portion of the first through-hole h3a. The plurality of first through-holes h3a are located in front of the signal conductor layer 20 when viewed downward. The plurality of first through-holes h3a are aligned in a row along the left-right axis.

The insulator layer 16b (second insulator layer) includes a plurality of second through-holes h3b that penetrate the insulator layer 16b (second insulator layer) along the up-down axis (Z-axis). The plurality of second through-holes h3b each have a tapered shape that becomes narrower in the downward direction (negative direction of the Z-axis). Therefore, the lower end portion of the second through-hole h3b is narrower than the upper end portion of the second through-hole h3b. The plurality of second through-holes h3b are located in front of the signal conductor layer 20 when viewed downward. The plurality of second through-holes h3b are aligned in a row along the left-right axis. In other words, the plurality of second through-holes h3b are aligned along a signal line.

The plurality of second through-holes h3b overlap the plurality of first through-holes h3a when viewed downward. When viewed upward (positive direction of the Z-axis), the area of the upper end portion (end portion on the positive side of the Z-axis) of the second through-hole h3b is larger than the area of the lower end portion (end portion on the negative side of the Z-axis) of the first through-hole h3a. As a result, when viewed upward (positive direction of the Z-axis), the lower end portion (end portion on the negative side of the Z-axis) of the first through-hole h3a fits into the upper end portion (end portion on the positive side of the Z-axis) of the second through-hole h3b. Specifically, when viewed upward, the lower end portion of the first through-hole h3a does not protrude from the upper end portion of the second through-hole h3b. The plurality of second through-holes h3b are thus connected to the plurality of first through-holes h3a.

The first interlayer connection conductor v3a extends along the up-down axis (Z-axis) inside the first through-hole h3a and the second through-hole h3b. An upper end portion UP of the first interlayer connection conductor v3a is in contact with the first ground conductor layer 22. A lower end portion DP of the first interlayer connection conductor v3a is in contact with the third ground conductor layer 25. The first interlayer connection conductor v3a has a middle portion MP located between the upper end portion UP (end portion on the positive side of the Z-axis) of the first interlayer connection conductor v3a and the lower end portion DP (end portion on the negative side of the Z-axis) of the first interlayer connection conductor v3a. The middle portion MP is located at the same or substantially the same position as the center CP of the first interlayer connection conductor v3a on the up-down axis (Z-axis). However, the middle portion MP does not have to coincide with the center CP. The first interlayer connection conductor v3a includes a first section A1 having a tapered shape that becomes narrower from the upper end portion UP (end portion on the positive side of the Z-axis) toward the middle portion MP, and a second section A2 having a tapered shape that becomes narrower from the lower end portion DP (end portion on the negative side of the Z-axis) toward the middle portion MP.

A space Sp1 exists between the boundary of the insulator layer 16a (first insulator layer) and the insulator layer 16b (second insulator layer) and the first interlayer connection conductor v3a. The space Sp1 also exists between the inner circumferential surface of the second through-hole h3b and the center CP of the first interlayer connection conductor v3a on the up-down axis (Z-axis). The space Sp1 faces at least a portion of the inner circumferential surface of the first through-hole h3a and faces at least a portion of the inner circumferential surface of the second through-hole h3b. In the present example embodiment, the space Sp1 faces the entire or substantially the entire inner circumferential surface of the first through-hole h3a and the entire or substantially the entire inner circumferential surface of the second through-hole h3b. Therefore, the first interlayer connection conductor v3a is in contact only with the upper end of the inner circumferential surface of the first through-hole h3a and the upper end of the inner circumferential surface of the second through-hole h3b, and is not in contact with any portion of the inner circumferential surface of the first through-hole h3a other than the upper end, nor with any portion of the inner circumferential surface of the second through-hole h3b other than the upper end. Therefore, the space Sp1 causes the first interlayer connection conductor v3a not to come into contact with the boundary between the insulator layer 16a (first insulator layer) and the insulator layer 16b (second insulator layer).

When viewed downward (in the negative direction of the Z-axis), at least a portion of the side surface of the first interlayer connection conductor v3a in the first section A1, at least a portion of the side surface of the first interlayer connection conductor v3a in the second section A2, and at least a portion of the space Sp1 overlap each other. This causes a portion of the space Sp1 to be located between the side surface of the first interlayer connection conductor v3a in the first section A1 and the side surface of the first interlayer connection conductor v3a in the second section A2.

The plurality of first interlayer connection conductors v3b each electrically connect the second ground conductor layer 24 and the third ground conductor layer 25. More specifically, the insulator layer 16d includes a plurality of first through-holes h3d that penetrate the insulator layer 16d along the up-down axis. The plurality of first through-holes h3d each have a tapered shape that becomes narrower in the downward direction. Therefore, the lower end portion of the first through-hole h3d is narrower than the upper end portion of the first through-hole h3d. The plurality of first through-holes h3d are located in front of the signal conductor layer 20 when viewed downward. The plurality of first through-holes h3d are aligned in a row along the left-right axis.

The insulator layer 16c includes a plurality of second through-holes h3c that penetrate the insulator layer 16c along the up-down axis. The plurality of second through-holes h3c each have a tapered shape that becomes narrower in the upward direction. Therefore, the upper end portion of the second through-hole h3c is narrower than the lower end portion of the second through-hole h3c. The plurality of second through-holes h3c are located in front of the signal conductor layer 20 when viewed downward. The plurality of second through-holes h3c are aligned in a row along the left-right axis. The plurality of second through-holes h3c are aligned along the signal line.

The plurality of second through-holes h3c overlap the plurality of first through-holes h3d when viewed downward. When viewed upward, the area of the lower end portion of the second through-hole h3c is larger than the area of the upper end portion of the first through-hole h3d. As a result, when viewed upward, the lower end portion of the first through-hole h3d fits into the upper end portion of the second through-hole h3c. Specifically, when viewed upward, the lower end portion of the first through-hole h3d does not protrude from the upper end portion of the second through-hole h3c. The plurality of second through-holes h3c are thus connected to the plurality of first through-holes h3d.

The first interlayer connection conductor v3b extends along the up-down axis inside the first through-hole h3d and the second through-hole h3c. An upper end portion UP of the first interlayer connection conductor v3b is in contact with the third ground conductor layer 25. A lower end portion DP of the first interlayer connection conductor v3b is in contact with the second ground conductor layer 24. The first interlayer connection conductor v3b includes a middle portion MP located between the upper end portion UP of the first interlayer connection conductor v3b and the lower end portion DP of the first interlayer connection conductor v3b. The middle portion MP is located at the same or substantially the same position as the center CP of the first interlayer connection conductor v3b on the up-down axis (Z-axis). However, the middle portion MP does not have to coincide with the center CP. The first interlayer connection conductor v3b includes a first section A1 having a tapered shape that becomes narrower from the upper end portion UP toward the middle portion MP, and a second section A2 having a tapered shape that becomes narrower from the lower end portion DP toward the middle portion MP.

A space Sp2 exists between the boundary of the insulator layer 16d and the insulator layer 16c and the first interlayer connection conductor v3b. The space Sp2 faces at least a portion of the inner circumferential surface of the first through-hole h3d and faces at least a portion of the inner circumferential surface of the second through-hole h3c. In the present example embodiment, the space Sp2 faces the entire or substantially the entire inner circumferential surface of the first through-hole h3d and the entire or substantially the entire inner circumferential surface of the second through-hole h3c. Therefore, the first interlayer connection conductor v3b is in contact only with the lower end of the inner circumferential surface of the first through-hole h3d and the upper end of the inner circumferential surface of the second through-hole h3c, and is not in contact with any portion of the inner circumferential surface of the first through-hole h3d other than the lower end, nor with any portion of the inner circumferential surface of the second through-hole h3c other than the upper end. Therefore, the space Sp2 causes the first interlayer connection conductor v3b not to come into contact with the boundary between the insulator layer 16d and the insulator layer 16c.

The plurality of first interlayer connection conductors v4 have a structure front-back symmetrical to that of the plurality of first interlayer connection conductors v3, and thus description thereof will be omitted. A ground potential is connected to the first ground conductor layer 22 (first conductor layer), the third ground conductor layer 25 (second conductor layer), and the first interlayer connection conductors v3a, v3b, v4a, and v4b as described above.

As shown in FIG. 1, the protective layer 18a covers a portion of the upper main surface of the multilayer body 12. The protective layer 18a thus protects the first ground conductor layer 22. However, the protective layer 18a has rectangular or substantially rectangular openings H1 to H6 provided therein. The opening H1 overlaps the mounting electrode 26a when viewed downward. This allows the mounting electrode 26a to be exposed to the outside of the multilayer substrate 10. The opening H2 is located in front of the opening H1. A portion of the first ground conductor layer 22 is exposed to the outside of the multilayer substrate 10 through the opening H2. The opening H3 is located behind the opening H1. A portion of the first ground conductor layer 22 is exposed to the outside of the multilayer substrate 10 through the opening H3. This allows the portion of the first ground conductor layer 22 to define and function as a ground terminal. The openings H4 to H6 have a structure left-right symmetrical to that of the openings H1 to H3, and thus description thereof will be omitted.

The protective layer 18b covers the lower main surface of the multilayer body 12. The protective layer 18b thus protects the second ground conductor layer 24. The material of such protective layers 18a and 18b is different from the material of the insulator layers 16a to 16d. The protective layers 18a and 18b are, for example, solder resists. The solder resist is made of, for example, a composition including an alkali-soluble resin, a photopolymerization initiator, an epoxy resin for improving heat resistance, or inorganic powder.

The signal conductor layer 20, the first ground conductor layer 22, the second ground conductor layer 24, the third ground conductor layer 25, and the mounting electrodes 26a and 26b as described above are formed, for example, by etching metal foil provided on the upper main surface or the lower main surface of the insulator layers 16a to 16d. The metal foil is, for example, copper foil. The signal conductor layer 20, the first ground conductor layer 22, the second ground conductor layer 24, the third ground conductor layer 25, and the mounting electrodes 26a and 26b are thus metal foil provided on the main surfaces of the insulator layers 16a to 16d.

The first interlayer connection conductors v1 to v4 are, for example, via hole conductors. The first interlayer connection conductors v1 to v4 are made of, for example, an alloy including Sn. The first interlayer connection conductors v1 to v4 are made of, for example, solder. However, the melting point of the material of the first interlayer connection conductors v1 to v4 may be equal to or lower than the melting point of the solder used to mount the electronic components. As a result, stress applied to the first interlayer connection conductors v1 to v4 is reduced if the first interlayer connection conductors v1 to v4 melt when the electronic components are mounted. This reduces or prevents damage to the first interlayer connection conductors v1 to v4.

When viewed downward (in the negative direction of the Z-axis), at least a portion of the side surface of the first interlayer connection conductor v3a in the first section A1, at least a portion of the side surface of the first interlayer connection conductor v3a in the second section A2, and at least a portion of the space Sp1 overlap each other. This causes a portion of the space Sp1 to be located between the side surface of the first interlayer connection conductor v3a in the first section A1 and the side surface of the first interlayer connection conductor v3a in the second section A2. This makes it less likely that a capacitance will be formed between the side surface of the first interlayer connection conductor v3a in the first section A1 and the side surface of the first interlayer connection conductor v3a in the second section A2. This results in reducing the formation of an LC resonance circuit between the side surface of the first interlayer connection conductor v3a in the first section A1 and the side surface of the first interlayer connection conductor v3a in the second section A2, and thus unwanted resonance is less likely to be generated.

### Method for Manufacturing Multilayer Substrate 10

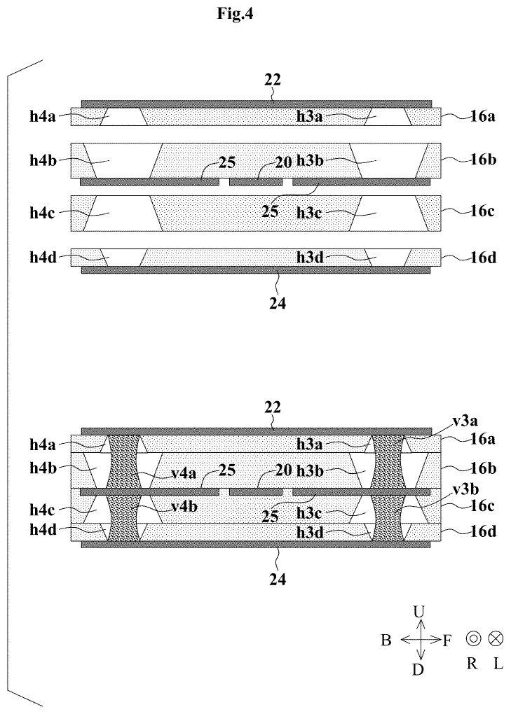

Next, an example of a method for manufacturing the multilayer substrate 10 according to an example embodiment of the present invention will be described with reference to the drawings. FIG. 4 is a sectional view of the multilayer substrate 10 during manufacture.

First, the insulator layer 16a (first insulator layer) and the insulator layer 16b (second insulator layer), each including the upper main surface (positive main surface) and the lower main surface (negative main surface), aligned along the up-down axis (Z-axis) are prepared (preparation step). Specifically, the insulator layers 16a, 16b, and 16d with metal foil attached to the upper main surface or the lower main surface are prepared. Then, the metal foil is patterned to form the signal conductor layer 20, the first ground conductor layer 22, the second ground conductor layer 24, the third ground conductor layer 25, and the mounting electrodes 26a and 26b. No metal foil is attached to the upper main surface and the lower main surface of the insulator layer 16c.

Next, as shown in FIG. 2 and the upper portion of FIG. 4, the first through-hole h1a, the plurality of first through-holes h3a, and a plurality of first through-holes h4a are formed, which penetrate the insulator layer 16a (first insulator layer) along the up-down axis (Z-axis) (first through-hole formation step). At the same time, the second through-hole h1b, the plurality of second through-holes h3b, and a plurality of second through-holes h4b are formed, which penetrate the insulator layer 16b (second insulator layer) along the up-down axis (Z-axis) (second through-hole formation step). Similarly, the plurality of first through-holes h3d and a plurality of first through-holes h4d are formed, which penetrate the insulator layer 16d along the up-down axis, and the plurality of second through-holes h3c and a plurality of second through-holes h4c are formed, which penetrate the insulator layer 16c along the up-down axis.

Next, the insulator layers 16a to 16d are arranged in this order from top to bottom. Then, the first through-hole h1a, the plurality of first through-holes h3a, the plurality of first through-holes h4a, the second through-hole h1b, the plurality of second through-holes h3b, and the plurality of second through-holes h4b are filled with solder. Thereafter, a multilayer body, in which the insulator layers 16a to 16d are stacked, is pressure-bonded (pressure bonding step). In the pressure bonding step, for example, an isotropic press is used. In the pressure bonding step, heat treatment is also performed. The insulator layer 16a (first insulator layer) and the insulator layer 16b (second insulator layer) are thus laminated so that the lower main surface (negative main surface) of the insulator layer 16a (first insulator layer) is in contact with the upper main surface (positive main surface) of the insulator layer 16b (second insulator layer). At the same time, the first interlayer connection conductors v1, v2, v3, and v4 are formed so as to extend along the up-down axis (Z-axis) inside the first through-holes h1a, h3a, and h4a and the second through-holes h1b, h3b, and h4b (first interlayer connection conductor formation step).

Finally, as shown in FIGS. 2 and 3, the protective layers 18a and 18b are formed on the multilayer body 12. Through the above steps, the multilayer substrate 10 is completed.

### Advantageous Effects

The multilayer substrate 10 can reduce or prevent damage to the first interlayer connection conductors v1 to v4. This will be described below by taking the first interlayer connection conductor v3a as an example. A multilayer substrate provided with a first interlayer connection conductor penetrating insulator layers adjacent to each other in the up-down direction will be considered as a comparative example. In general, when a force is applied to the multilayer substrate, a large force is applied to the first interlayer connection conductor at the boundary between the two insulator layers adjacent to each other in the up-down direction. Such a large force applied to the first interlayer connection conductor may damage the first interlayer connection conductor.

Therefore, in the multilayer substrate 10, when viewed upward, the area of the upper end portion of the second through-hole h3b is larger than the area of the lower end portion of the first through-hole h3a. This makes it easier for the space Sp1 to be provided between the boundary of the insulator layer 16a and the insulator layer 16b and the first interlayer connection conductor v3a. This reduces the application of a large force to the first interlayer connection conductor v3a at the boundary between the insulator layer 16a and the insulator layer 16b. As a result, the multilayer substrate 10 can reduce or prevent damage to the first interlayer connection conductor v3a.

In the multilayer substrate 10, a capacitance is less likely to be generated between the first interlayer connection conductors v1 to v4 and the surrounding conductors. This will be described below by taking the first interlayer connection conductor v3a as an example. In general, the first interlayer connection conductor faces the surrounding conductor with an insulator layer interposed therebetween. In this case, a capacitance is generated between the first interlayer connection conductor and the surrounding conductor. Such a capacitance may cause electrical characteristics of an electric circuit inside the multilayer substrate to change from a desired value. For example, when a high-frequency signal is transmitted to the first interlayer connection conductor and the surrounding conductor, isolation between the first interlayer connection conductor and the surrounding conductor deteriorates. When the first interlayer connection conductor is connected to the ground potential and a high-frequency signal is transmitted to the surrounding conductor, the characteristic impedance of the surrounding conductor decreases.

Therefore, the multilayer substrate 10 includes the space Sp1 between the boundary of the insulator layer 16a and the insulator layer 16b and the first interlayer connection conductor v3a. This reduces the amount of the insulator layer between the first interlayer connection conductor v3a and other conductors. Therefore, a dielectric constant decreases between the first interlayer connection conductor v3a and the other conductors. Thus, in the multilayer substrate 10, a capacitance is less likely to be generated between the first interlayer connection conductor v3a and the surrounding conductors.

In the multilayer substrate 10, when viewed upward, the area of the upper end portion of the second through-hole h3b is larger than the area of the lower end portion of the first through-hole h3a. Particularly, in the multilayer substrate 10, when viewed upward, the lower end portion of the first through-hole h3a fits into the upper end portion of the second through-hole h3b. This makes it less likely to change the area where the upper end portion of the second through-hole h3b overlaps the lower end portion of the first through-hole h3a, when viewed upward, even if the second through-hole h3b shifts forward, backward, left, or right relative to the first through-hole h3a when the insulator layers 16a to 16d are laminated.

In the multilayer substrate 10, when viewed upward, the area of the upper end portion of the second through-hole h3b is larger than the area of the lower end portion of the first through-hole h3a. As a result, the thickness of the first interlayer connection conductor v3a is determined by the thickness of the first through-hole h3a. Specifically, the first interlayer connection conductor v3a with a small thickness is easily formed. Furthermore, the position of f the first interlayer connection conductor v3a is determined by the lower end portion of the first through-hole h3a with a small area. This makes it less likely that the first interlayer connection conductor v3a will be biased to forward, backward, left, or right in the first through-hole h3a and the second through-hole h3b. As a result, the space Sp1 is easily provided.

The multilayer substrate 10 can also reduce or prevent damage to the first interlayer connection conductors v1 to v4 for the following reasons. This will be described below by taking the first interlayer connection conductor v3a as an example. More specifically, the center CP of the first interlayer connection conductor v3a on the up-down axis is thin and therefore prone to damage. However, the space Sp1 exists between the inner circumferential surface of the second through-hole h3b and the center CP of the first interlayer connection conductor v3a on the up-down axis. This makes it less likely that a large force will be applied to the center CP of the first interlayer connection conductor v3a on the up-down axis. As a result, the multilayer substrate 10 can reduce or prevent damage to the first interlayer connection conductor v3a.

The multilayer substrate 10 can also reduce or prevent damage to the first interlayer connection conductors v1 to v4 for the following reason. This will be described below by taking the first interlayer connection conductor v3a as an example. More specifically, the first interlayer connection conductor v3a includes the first section A1 having a tapered shape that becomes narrower from the upper end portion UP toward the middle portion MP, and the second section A2 having a tapered shape that becomes narrower from the lower end portion DP toward the middle portion MP. As a result, the first interlayer connection conductor v3a has a shape that is narrow around the middle portion MP. Therefore, the space Sp1 is easily provided between the boundary of the insulator layers 16a and the insulator layer 16b and the first interlayer connection conductor v3a. This reduces or prevents the application of a large force to the first interlayer connection conductor v3a at the boundary between the insulator layer 16a and the insulator layer 16b. As a result, the multilayer substrate 10 can reduce or prevent damage to the first interlayer connection conductor v3a.

In the multilayer substrate 10, the first interlayer connection conductor v3a includes the first section A1 having a tapered shape that becomes narrower from the upper end portion UP toward the middle portion MP, and the second section A2 having a tapered shape that becomes narrower from the lower end portion DP toward the middle portion MP. This increases the area of a joint portion between the first interlayer connection conductor v3a and the first ground conductor layer 22, and the area of a joint portion between the first interlayer connection conductor v3a and the third ground conductor layer 25. As a result, the bonding strength between the first interlayer connection conductor v3a and the first ground conductor layer 22, and the bonding strength between the first interlayer connection conductor v3a and the third ground conductor layer 25 are improved.

In the multilayer substrate 10, the first through-hole h3a has a tapered shape that becomes narrower in the upward direction. The second through-hole h3b has a tapered shape that becomes narrower in the downward direction. This reduces the area of the portion where the first ground conductor layer 22 is exposed in the first through-hole h3a, and reduces the area of the portion where the third ground conductor layer 25 is exposed in the second through-hole h3b.

In the multilayer substrate 10, the first through-hole h3a has a tapered shape that becomes narrower in the upward direction. The second through-hole h3b has a tapered shape that becomes narrower in the downward direction. This makes it easier for the space Sp1 to be provided between the boundary of the insulator layers 16a and 16b and the first interlayer connection conductor v3a.

In the multilayer substrate 10, when viewed downward, at least a portion of the side surface of the first interlayer connection conductor v1 in the first section A1, at least a portion of the side surface of the first interlayer connection conductor v1 in the second section A2, and at least a portion of the space Sp0 overlap each other. This causes a portion of the space Sp0 to be located between the side surface of the first interlayer connection conductor v1 in the first section A1 and the side surface of the first interlayer connection conductor v1 in the second section A2. This makes it less likely that a capacitance will be generated between the side surface of the first interlayer connection conductor v1 in the first section A1 and the side surface of the first interlayer connection conductor v1 in the second section A2. This results in reducing the formation of an LC resonance circuit between the side surface of the first interlayer connection conductor v1 in the first section A1 and the side surface of the first interlayer connection conductor v1 in the second section A2, and thus unwanted resonance is less likely to be generated.

### First Modification

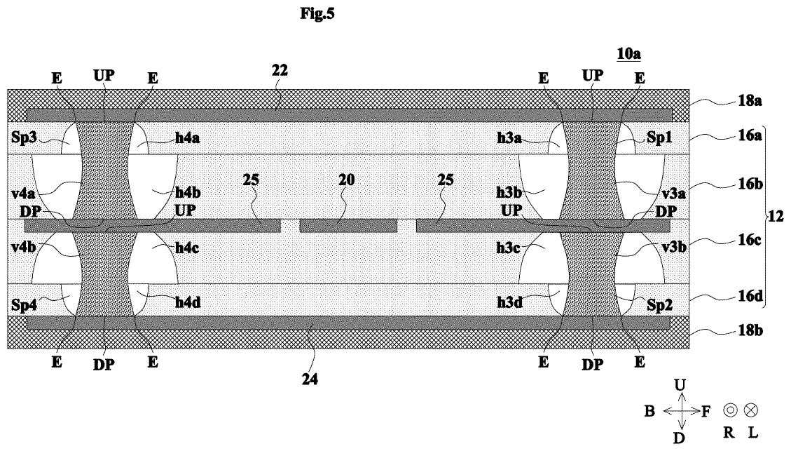

A multilayer substrate 10a according to a first modification of an example embodiment of the present invention will be described below with reference to the drawings. FIG. 5 is a sectional view of the multilayer substrate 10a.

The multilayer substrate 10a differs from the multilayer substrate 10 in the shape of the first through-hole h3a and the shape of the second through-hole h3b. More specifically, the inner circumferential surface of the first through-hole h3a and the inner circumferential surface of the second through-hole h3b have a dome shape. In a cross section parallel or substantially parallel to the up-down axis, the inner circumferential surface of the first through-hole h3a and the inner circumferential surface of the second through-hole h3b have a curved shape. This increases the space Sp1. The rest of the structure of the multilayer substrate 10a is the same or substantially the same as that of the multilayer substrate 10, and thus description thereof will be omitted. The multilayer substrate 10a achieves the same advantageous effects as those of the multilayer substrate 10.

### Second Modification

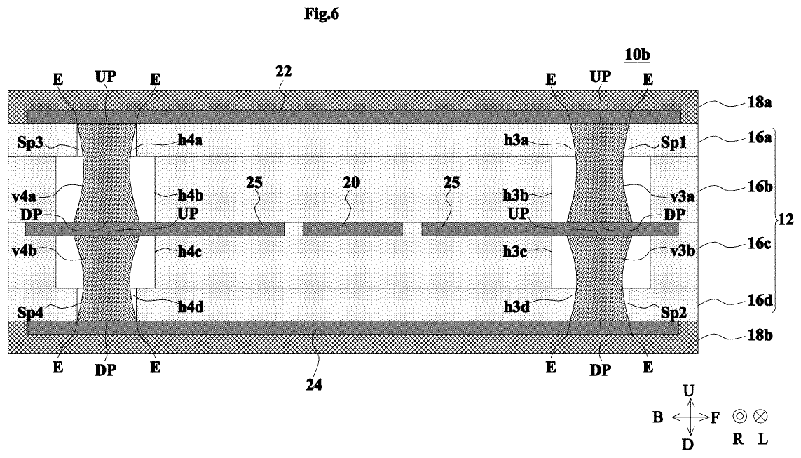

A multilayer substrate 10b according to a second modification of an example embodiment of the present invention will be described below with reference to the drawings. FIG. 6 is a sectional view of the multilayer substrate 10b.

The multilayer substrate 10b differs from the multilayer substrate 10 in the shape of the first through-hole h3a and the shape of the second through-hole h3b. More specifically, the shape of the first through-hole h3a and the shape of the second through-hole h3b are cylindrical. This facilitates the formation of the first through-hole h3a and the second through-hole h3b. The rest of the structure of the multilayer substrate 10b is the same or substantially the same as that of the multilayer substrate 10, and thus description thereof will be omitted. The multilayer substrate 10b achieves the same advantageous effects as those of the multilayer substrate 10.

### Third Modification

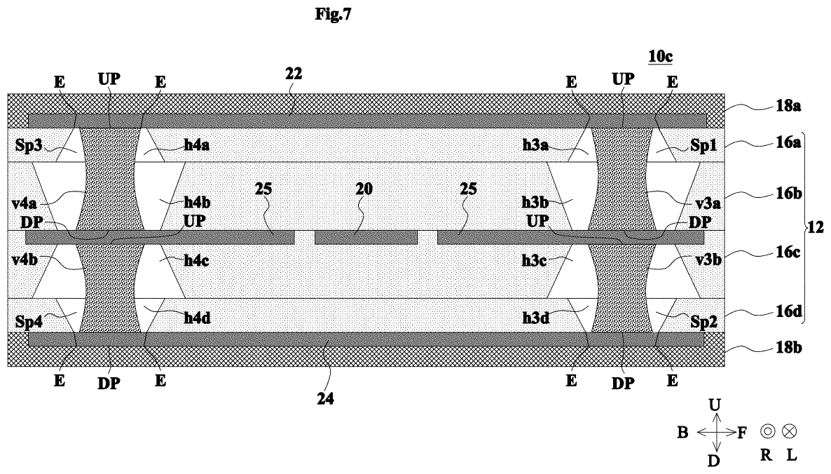

A multilayer substrate 10c according to a third modification of an example embodiment of the present invention will be described below with reference to the drawings. FIG. 7 is a sectional view of the multilayer substrate 10c.

The multilayer substrate 10c differs from the multilayer substrate 10 in the shape of the first interlayer connection conductor v3a. More specifically, in the multilayer substrate 10c, the upper end portion of the first interlayer connection conductor v3a is not in contact with an outer edge E of the upper end portion of the first through-hole h3a. This increases the space Sp1. The rest of the structure of the multilayer substrate 10c is the same or substantially the same as that of the multilayer substrate 10, and thus description thereof will be omitted. The multilayer substrate 10c achieves the same advantageous effects as those of the multilayer substrate 10.

### Fourth Modification

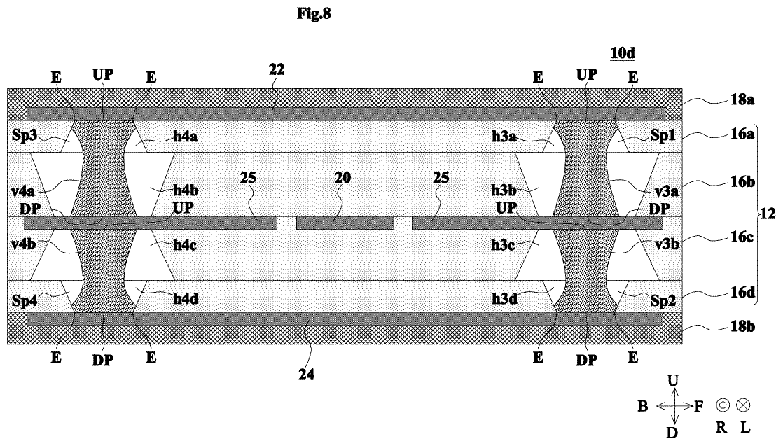

A multilayer substrate 10d according to a fourth modification of an example embodiment of the present invention will be described below with reference to the drawings. FIG. 8 is a sectional view of the multilayer substrate 10d.

The multilayer substrate 10d differs from the multilayer substrate 10 in the shape of the first interlayer connection conductor v3a. More specifically, the upper portion of the first interlayer connection conductor v3a is in contact with the upper part of the inner circumferential surface of the first through-hole h3a. The rest of the structure of the multilayer substrate 10d is the same or substantially the same as that of the multilayer substrate 10, and thus description thereof will be omitted. The multilayer substrate 10d achieves the same advantageous effects as those of the multilayer substrate 10.

### Fifth Modification

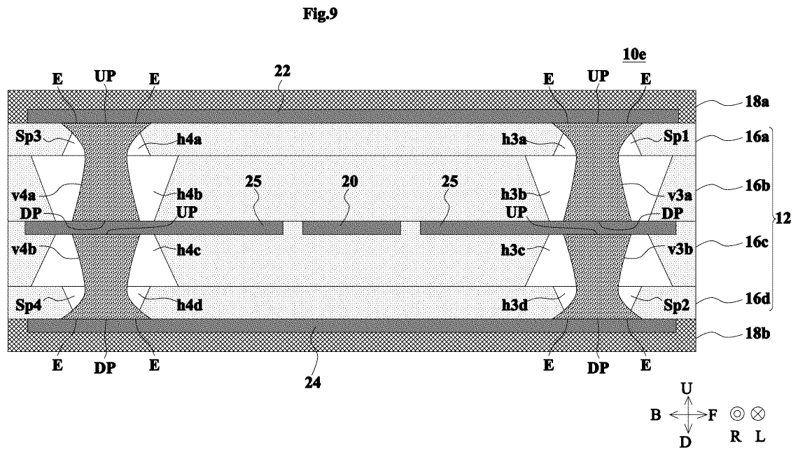

A multilayer substrate 10e according to a fifth modification of an example embodiment of the present invention will be described below with reference to the drawings. FIG. 9 is a sectional view of the multilayer substrate 10e.

The multilayer substrate 10e differs from the multilayer substrate 10 in the shape of the first interlayer connection conductor v3a. More specifically, the upper end portion of the first interlayer connection conductor v3a penetrates between the lower main surface of the first ground conductor layer 22 and the upper main surface of the insulator layer 16a. This improves the bonding strength between the first interlayer connection conductor v3a and the first ground conductor layer 22.

When viewed downward (in the negative direction of the Z-axis), at least a portion of the side surface of the first interlayer connection conductor v3a in the first section A1, at least a portion of the side surface of the first interlayer connection conductor v3a in the second section A2, and at least a portion of the space Sp1 overlap each other. This causes a portion of the space Sp1 to be located between the side surface of the first interlayer connection conductor v3a in the first section A1 and the side surface of the first interlayer connection conductor v3a in the second section A2. This makes it less likely that a capacitance will be generated between the side surface of the first interlayer connection conductor v3a in the first section A1 and the side surface of the first interlayer connection conductor v3a in the second section A2. This results in reducing the formation of an LC resonance circuit between the side surface of the first interlayer connection conductor v1 in the first section A1 and the side surface of the first interlayer connection conductor v3a in the second section A2, and thus unwanted resonance is less likely to be generated. The rest of the structure of the multilayer substrate 10e is the same or substantially the same as that of the multilayer substrate 10, and thus description thereof will be omitted. The multilayer substrate 10e achieves the same advantageous effects as those of the multilayer substrate 10.

### Sixth Modification

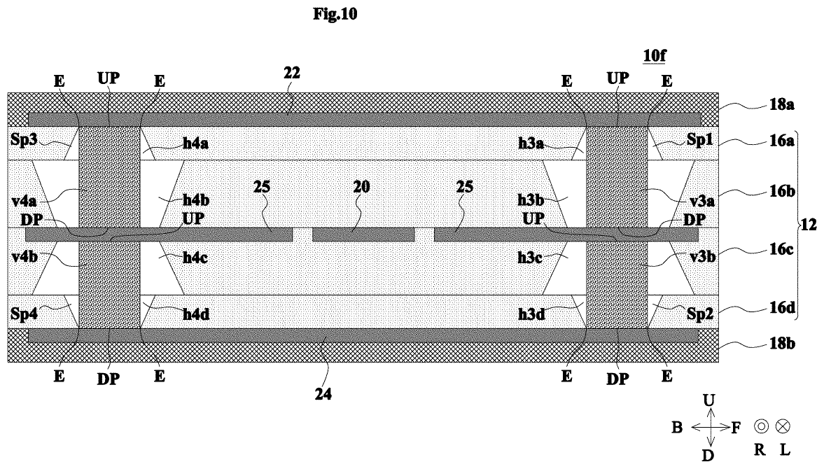

A multilayer substrate 10f according to a sixth modification of an example embodiment of the present invention will be described below with reference to the drawings. FIG. 10 is a sectional view of the multilayer substrate 10f.

The multilayer substrate 10f differs from the multilayer substrate 10 in the shape of the first interlayer connection conductor v3a. The first interlayer connection conductor v3a has a cylindrical shape. As a result, when a shear stress is applied to the first interlayer connection conductor v3a in the left or right direction, the force is applied uniformly to the entire or substantially the entire first interlayer connection conductor v3a. This results in reducing or preventing damage to the first interlayer connection conductor v3a. The rest of the structure of the multilayer substrate 10f is the same or substantially the same as that of the multilayer substrate 10, and thus description thereof will be omitted. The multilayer substrate 10f achieves the same advantageous effects as those of the multilayer substrate 10.

### Seventh Modification

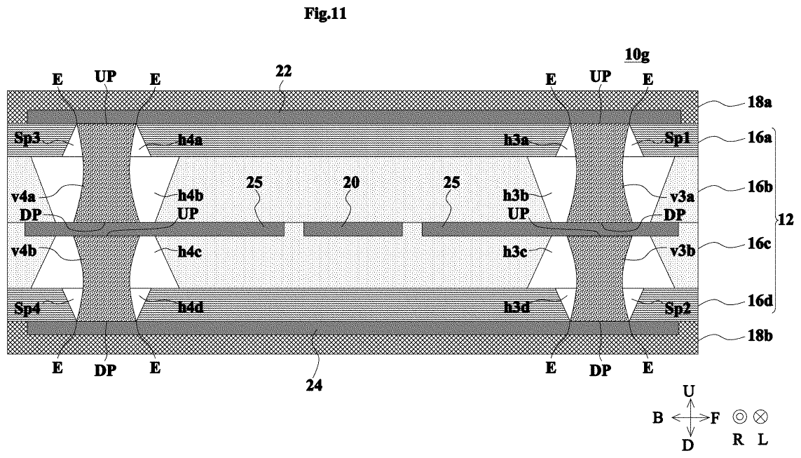

A multilayer substrate 10g according to a seventh modification of an example embodiment of the present invention will be described below with reference to the drawings. FIG. 11 is a sectional view of the multilayer substrate 10g.

The multilayer substrate 10g differs from the multilayer substrate 10 in the materials of the insulator layers 16a and 16d. The material of the insulator layer 16a (first insulator layer) is different from the material of the insulator layer 16b (second insulator layer). The material of the insulator layer 16d is different from the material of the insulator layer 16c. The insulator layers 16a and 16d define and function as adhesive layers. It is difficult to make the thickness of the insulator layers 16a and 16d on the up-down axis match the target value. Therefore, the thickness of the insulator layers 16a and 16d on the up-down axis may be reduced to lower the dielectric constant of the insulator layers 16b and 16c, and the thickness of the insulator layers 16b and 16c on the up-down axis may be increased. This makes it possible to obtain excellent electrical characteristics and reduce or prevent variations in the electrical characteristics. The insulator layers 16a and 16d may include air bubbles to reduce the dielectric constant of the insulator layers 16a and 16d. The rest of the structure of the multilayer substrate 10g is the same or substantially the same as that of the multilayer substrate 10, and thus description thereof will be omitted. The multilayer substrate 10g achieves the same or substantially the same advantageous effects as those of the multilayer substrate 10.

### Eighth Modification

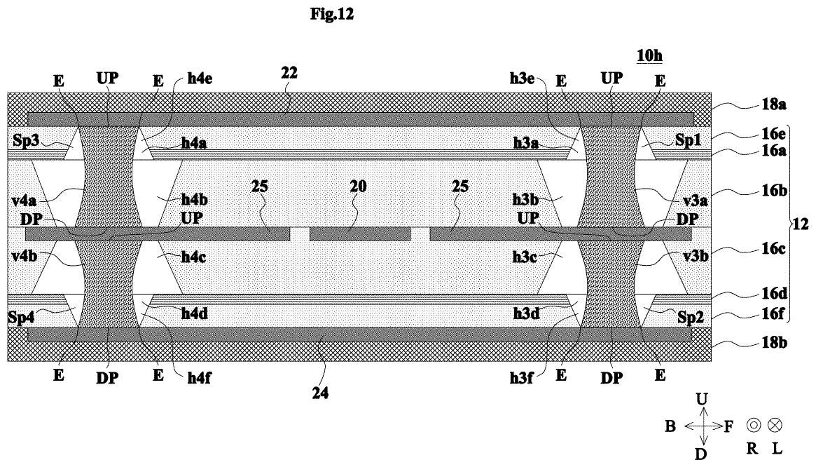

A multilayer substrate 10h according to an eighth modification of an example embodiment of the present invention will be described below with reference to the drawings. FIG. 12 is a sectional view of the multilayer substrate 10h.

The multilayer substrate 10h differs from the multilayer substrate 10 in the material of the insulator layers 16a and 16d, and in that the multilayer body 12 further includes insulator layers 16e and 16f (third insulator layers). The insulator layers 16e and 16f (third insulator layers) each include an upper main surface (positive main surface) and a lower main surface (negative main surface). The insulator layer 16e is located on the insulator layer 16a. Therefore, the lower main surface (negative main surface) of the insulator layer 16e (third insulator layer) is in contact with the upper main surface (positive main surface) of the insulator layer 16a (first insulator layer). The insulator layer 16f is located below the insulator layer 16d. Therefore, the upper main surface of the insulator layer 16f is in contact with the lower main surface of the insulator layer 16d. The material of the insulator layers 16e and 16f is the same as the material of the insulator layers 16b and 16c. The insulator layer 16a (first insulator layer) is an adhesive layer that bonds the insulator layer 16e (third insulator layer) and the insulator layer 16b (second insulator layer). The insulator layer 16d is an adhesive layer that bonds the insulator layer 16f and the insulator layer 16c. The insulator layer 16e and the insulator layer 16b are thus firmly bonded to each other. The insulator layer 16c and the insulator layer 16f are firmly bonded to each other.

The first ground conductor layer 22 is located on the upper main surface of the insulator layer 16e. The second ground conductor layer 24 is located on the lower main surface of the insulator layer 16f. Furthermore, the insulator layer 16e includes a third through-hole h3e. The insulator layer 16f includes a third through-hole h3f. The first interlayer connection conductor v3a extends along the up-down axis inside the third through-hole h3e. The first interlayer connection conductor v3b extends along the up-down axis inside the third through-hole h3f. As a result, the upper end portion of the first interlayer connection conductor v3a is in contact with the first ground conductor layer 22. The lower end portion of the first interlayer connection conductor v3b is in contact with the second ground conductor layer 24. The rest of the structure of the multilayer substrate 10h is the same or substantially the same as that of the multilayer substrate 10, and thus description thereof will be omitted. The multilayer substrate 10h achieves the same advantageous effects as those of the multilayer substrate 10.

### Ninth Modification

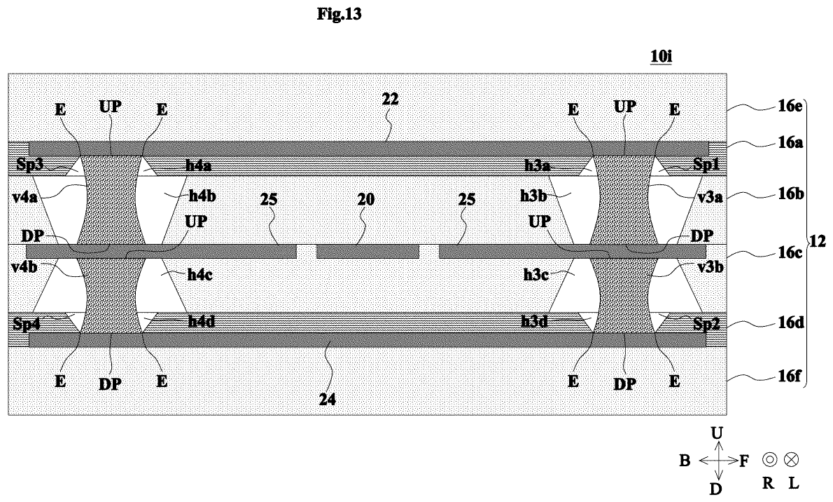

A multilayer substrate 10i according to a ninth modification of an example embodiment of the present invention will be described below with reference to the drawings. FIG. 13 is a sectional view of the multilayer substrate 10l.

The multilayer substrate 10i differs from the multilayer substrate 10 in the material of the insulator layers 16a and 16d, and in that the multilayer body 12 further includes insulator layers 16e and 16f (third insulator layers). The insulator layers 16e and 16f (third insulator layers) each include an upper main surface (positive main surface) and a lower main surface (negative main surface). The insulator layer 16e is located on the insulator layer 16a. Therefore, the lower main surface (negative main surface) of the insulator layer 16e (third insulator layer) is in contact with the upper main surface (positive main surface) of the insulator layer 16a (second insulator layer). The insulator layer 16f is located below the insulator layer 16d. Therefore, the upper main surface of the insulator layer 16f is in contact with the lower main surface of the insulator layer 16d. The material of the insulator layers 16e and 16f is the same as the material of the insulator layers 16b and 16c. The insulator layer 16a (first insulator layer) is an adhesive layer that bonds the insulator layer 16e (third insulator layer) and the insulator layer 16b (second insulator layer). The insulator layer 16d is an adhesive layer that bonds the insulator layer 16f and the insulator layer 16c. The insulator layer 16e and the insulator layer 16b are thus firmly bonded to each other. The insulator layer 16c and the insulator layer 16f are firmly bonded to each other.

The first ground conductor layer 22 is located on the lower main surface of the insulator layer 16e. The second ground conductor layer 24 is located on the upper main surface of the insulator layer 16f. As a result, the upper end portion of the first interlayer connection conductor v3a is in contact with the first ground conductor layer 22. The lower end portion of the first interlayer connection conductor v3b is in contact with the second ground conductor layer 24. The rest of the structure of the multilayer substrate 10i is the same or substantially the same as that of the multilayer substrate 10, and thus description thereof will be omitted. The multilayer substrate 10i achieves the same advantageous effects as those of the multilayer substrate 10.

### Tenth Modification

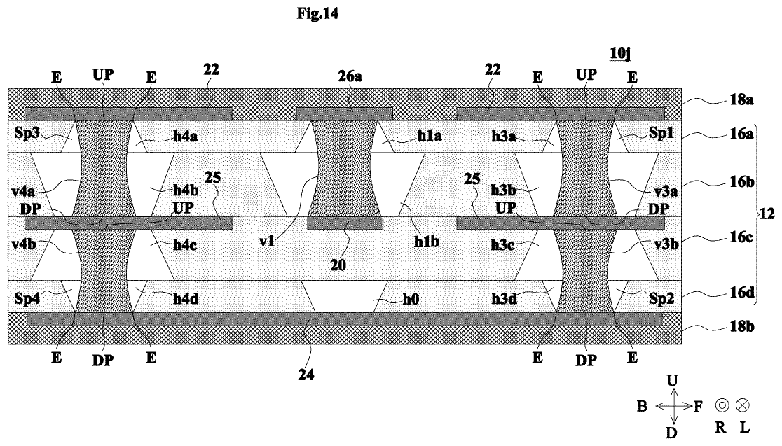

A multilayer substrate 10j according to a tenth modification of an example embodiment of the present invention will be described below with reference to the drawings. FIG. 14 is a sectional view of the multilayer substrate 10j.

The multilayer substrate 10j differs from the multilayer substrate 10 in that a through-hole h0 is provided in the insulator layer 16d. The through-hole h0 penetrates the insulator layer 16d along the up-down axis. The through-hole h0 overlaps the signal conductor layer 20 when viewed downward. By providing such a through-hole h0, the possibility is reduced that the first through-hole h1a and the second through-hole h1b will be crushed during pressure bonding of the insulator layers 16a to 16d. The through-hole h0 can also reduce the capacitance between the signal conductor layer 20 and the second ground conductor layer 24. This allows the characteristic impedance to be maintained constant. The rest of the structure of the multilayer substrate 10j is the same or substantially the same as that of the multilayer substrate 10, and thus description thereof will be omitted. The multilayer substrate 10j achieves the same advantageous effects as those of the multilayer substrate 10.

### Eleventh Modification

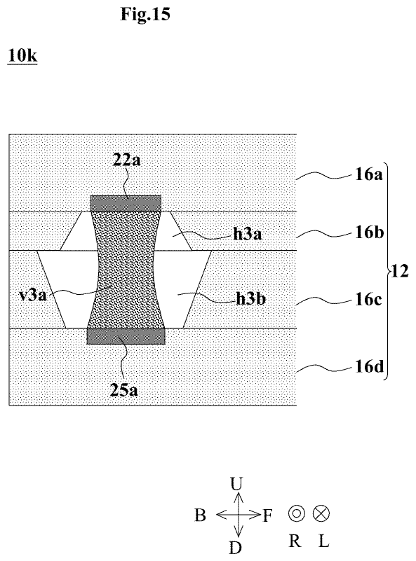

A multilayer substrate 10k according to an eleventh modification of an example embodiment of the present invention will be described below with reference to the drawings. FIG. 15 is a sectional view of a first interlayer connection conductor v3a and the vicinity thereof in the multilayer substrate 10k.

The multilayer substrate 10k differs from the multilayer substrate 10 in that a first conductor layer 22a corresponding to the first ground conductor layer 22 and a second conductor layer 25a corresponding to the third ground conductor layer 25 are smaller. More specifically, when viewed downward (in the negative direction of the Z-axis), the area of the first conductor layer 22a is smaller than the area of the upper end portion (end portion on the positive side of the Z-axis) of the first through-hole h3a. When viewed downward (in the negative direction of the Z-axis), the area of the second conductor layer 25a is smaller than the area of the lower end portion (end portion on the negative side of the Z-axis) of the second through-hole h3b. As a result, the first interlayer connection conductor v3a is narrowed, thus increasing the space around the first interlayer connection conductor v3a. By making the first conductor layer 22a and the second conductor layer 25a smaller, the capacitance with the surrounding conductors can be reduced. The rest of the structure of the multilayer substrate 10k is the same or substantially the same as that of the multilayer substrate 10, and thus description thereof will be omitted. The multilayer substrate 10k achieves the same advantageous effects as those of the multilayer substrate 10.

### Twelfth Modification

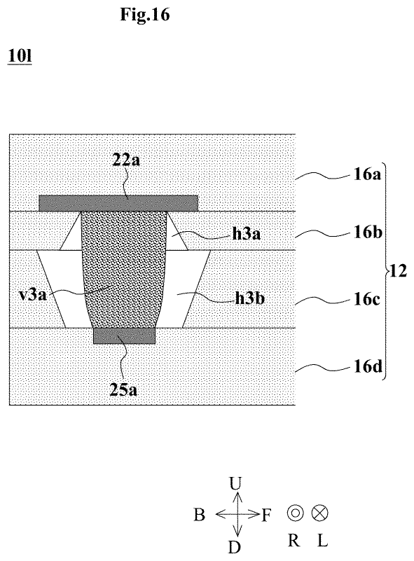

A multilayer substrate 10l according to a twelfth modification of an example embodiment of the present invention will be described below with reference to the drawings. FIG. 16 is a sectional view of a first interlayer connection conductor v3a and the vicinity thereof in the multilayer substrate 10l.

The multilayer substrate 10l differs from the multilayer substrate 10 in the shape of the first interlayer connection conductor v3a. More specifically, the first interlayer connection conductor v3a has a tapered shape that becomes narrower in the downward direction. With this structure, the narrow portion is at the position in contact with the second conductor layer 25a (the thickness of the first interlayer connection conductor v3a as a whole is larger than the thickness of the first interlayer connection conductor v3a at the point in contact with the second conductor layer 25a), thus improving the rigidity of the first interlayer connection conductor v3a. This results in reducing damage to the first interlayer connection conductor v3a. The rest of the structure of the multilayer substrate 10l is the same or substantially the same as that of the multilayer substrate 10, and thus description thereof will be omitted. The multilayer substrate 10l achieves the same advantageous effects as those of the multilayer substrate 10. In the example shown in FIG. 15, solder is in contact only with the surface of the second conductor layer 25a, but may also be in contact with the side surface thereof. This structure can increase the bonding strength between the first interlayer connection conductor v3a and the second conductor layer 25a.

### Thirteenth Modification

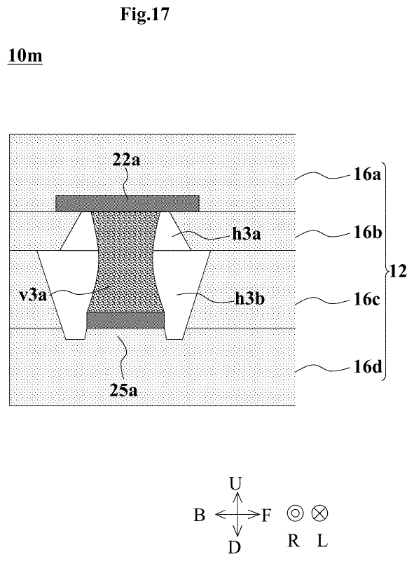

A multilayer substrate 10m according to a thirteenth modification of an example embodiment of the present invention will be described below with reference to the drawings. FIG. 17 is a sectional view of a first interlayer connection conductor v3a and the vicinity thereof in the multilayer substrate 10m.

The multilayer substrate 10m differs from the multilayer substrate 10 in the shape of the second through-hole h3b. More specifically, the second through-hole h3b extends to the insulator layer 16d. This makes it less likely that a capacitance will be generated between the first interlayer connection conductor v3a and the surrounding conductors. The rest of the structure of the multilayer substrate 10m is the same or substantially the same as that of the multilayer substrate 10, and thus description thereof will be omitted. The multilayer substrate 10m achieves the same advantageous effects as those of the multilayer substrate 10.

### Fourteenth Modification

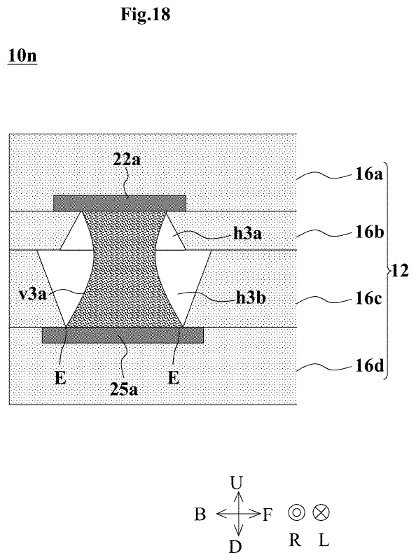

A multilayer substrate 10n according to a fourteenth modification of an example embodiment of the present invention will be described below with reference to the drawings. FIG. 18 is a sectional view of a first interlayer connection conductor v3a and the vicinity thereof in the multilayer substrate 10n.

The multilayer substrate 10n differs from the multilayer substrate 10 in the shape of the first interlayer connection conductor v3a. More specifically, in the multilayer substrate 10n, the lower end portion of the first interlayer connection conductor v3a is in contact with an outer edge E of the lower end portion of the second through-hole h3b. This allows the first interlayer connection conductor v3a to be firmly connected to the second conductor layer 25a. The rest of the structure of the multilayer substrate 10n is the same or substantially the same as that of the multilayer substrate 10, and thus description thereof will be omitted. The multilayer substrate 10n achieves the same advantageous effects as those of the multilayer substrate 10.

### Fifteenth Modification

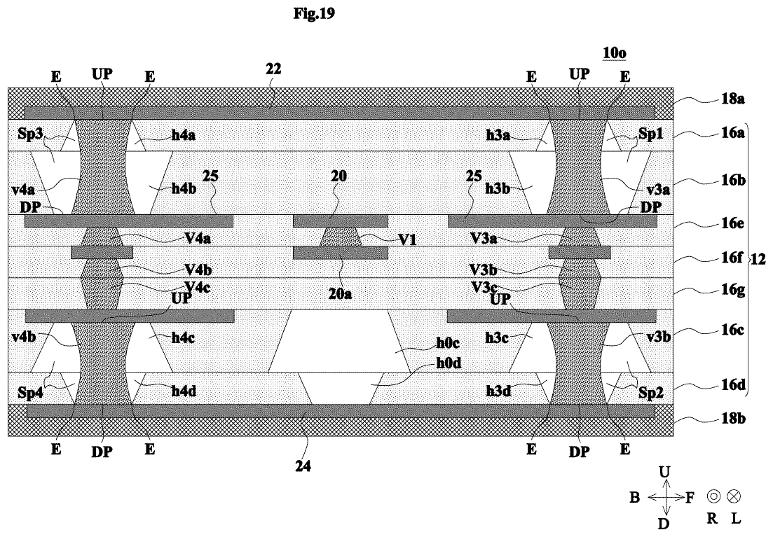

A multilayer substrate 10o according to a fifteenth modification of an example embodiment of the present invention will be described below with reference to the drawings. FIG. 19 is a sectional view of the multilayer substrate 10o.

The multilayer substrate 10o differs from the multilayer substrate 10 in further including a signal conductor layer 20a and second interlayer connection conductors V1, V3a to V3c, and V4a to V4c, and in that the multilayer body 12 further includes insulator layers 16e to 16g (third insulator layers). More specifically, the insulator layers 16e to 16g are laminated in this order from top to bottom between the insulator layer 16b and the insulator layer 16c.

The second interlayer connection conductors V1, V3a, and V4a penetrate the insulator layer 16e (third insulator layer) along the up-down axis (Z-axis). The second interlayer connection conductors V3b and V4b penetrate the insulator layer 16f (third insulator layer) along the up-down axis (Z-axis). The second interlayer connection conductors V3c and V4c penetrate the insulator layer 16g (third insulator layer) along the up-down axis (Z-axis). No spaces exist between the second interlayer connection conductors V1, V3a to V3c, and V4a to V4c and the insulator layers 16e to 16g (third insulator layers).

The second interlayer connection conductors V3a to V3c electrically connect the first interlayer connection conductor v3a and the first interlayer connection conductor v3b. The second interlayer connection conductors V4a to V4c electrically connect the first interlayer connection conductor v4a and the first interlayer connection conductor v4b. The second interlayer connection conductor V1 electrically connects the signal conductor layer 20 and the signal conductor layer 20a.

Here, the multilayer body 12 includes an upper main surface (positive main surface) and a lower main surface (negative main surface). The distance from the insulator layer 16a (first insulator layer) to the upper main surface (positive main surface) of the multilayer body 12 is shorter than the distance from the insulator layers 16e to 16c (third insulator layers) to the upper main surface (positive main surface) of the multilayer body 12. This improves the wiring density and strength of the multilayer substrate 10o. The rest of the structure of the multilayer substrate 10o is the same or substantially the same as that of the multilayer substrate 10, and thus description thereof will be omitted. The multilayer substrate 10o achieves the same advantageous effects as those of the multilayer substrate 10.

### Sixteenth Modification

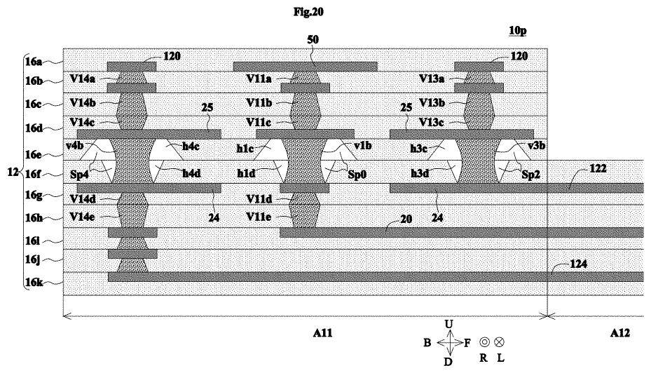

A multilayer substrate 10p according to a sixteenth modification of an example embodiment of the present invention will be described below with reference to the drawings. FIG. 20 is a sectional view of the multilayer substrate 10p.

The multilayer substrate 10p differs from the multilayer substrate 10 in the following respects.

The multilayer body 12 further includes insulator layers 16e to 16k.

The multilayer substrate 10p further includes a radiating conductor layer 50, ground conductor layers 120, 122, and 124, and second interlayer connection conductors V11a to V11e, V13a to V13c, and V14a to V14g.

The insulator layers 16a to 16k are laminated in this order from top to bottom. The second interlayer connection conductors V11a to V11e penetrate the insulator layers 16b to 16d, 16g, and 16h along the up-down axis. The second interlayer connection conductors V13a to V13c penetrate the insulator layers 16b to 16d along the up-down axis. The second interlayer connection conductors V14a to V14e penetrate the insulator layers 16b to 16d, 16g, and 16h along the up-down axis. No spaces exist between the second interlayer connection conductors V11a to V11e, V13a to V13c, and V14a to V14e and the insulator layers 16b to 16d, 16g, and 16h (third insulator layers).

The second interlayer connection conductors V11a to V11c electrically connect the radiating conductor layer 50 and the first interlayer connection conductor v1b. The second interlayer connection conductors V11d and Vile electrically connect the first interlayer connection conductor v1b and the signal conductor layer 20.

The second interlayer connection conductors V11d and V11e electrically the connect first interlayer connection conductor v1b and the signal conductor layer 20. The second interlayer connection conductors V11a to V11c electrically connect the radiating conductor layer 50 and the first interlayer connection conductor v1b. The second interlayer connection conductors V13a to V13c electrically connect the ground conductor layer 120 and the first interlayer connection conductor v3b. The second interlayer connection conductors V14a to V14c electrically connect the ground conductor layer 120 and the first interlayer connection conductor v4b. The second interlayer connection conductors V14d and V14e electrically connect the first interlayer connection conductor v4b and the ground conductor layer 124.

Here, the multilayer substrate 10p includes a first line section A11 and a second line section A12 aligned along the front-back axis (X-axis) orthogonal or substantially orthogonal to the up-down axis (Z-axis). The insulator layer 16f (first insulator layer) is located in the first line section A11 and the second line section A12. On the other hand, the insulator layer 16a and the insulator layers 16b to 16d (third insulator layers) are located in the first line section A11 and are not located in the second line section A12. As a result, the thickness of the first line section A11 on the up-down axis (Z-axis) is larger than the thickness of the second line section A12 on the up-down axis (Z-axis). Stress is easily concentrated at the boundary between the first line section A11 and the second line section A12. Particularly, stress is easily concentrated on the insulator layer 16f. Therefore, the insulator layer 16f (first insulator layer) is located in the first line section A11 and the second line section A12. As a result, spaces Sp0, Sp2, and Sp4 are deformed, thus reducing the application of a force to the first interlayer connection conductors v1b, v3b, and v4b. This makes it possible to improve the strength of the multilayer substrate 10p while ensuring the thickness of the multilayer substrate 10o on the up-down axis in the multilayer substrate 10p. The rest of the structure of the multilayer substrate 10p is the same or substantially the same as that of the multilayer substrate 10, and thus description thereof will be omitted. The multilayer substrate 10p achieves the same advantageous effects as those of the multilayer substrate 10.

### Electronic Device

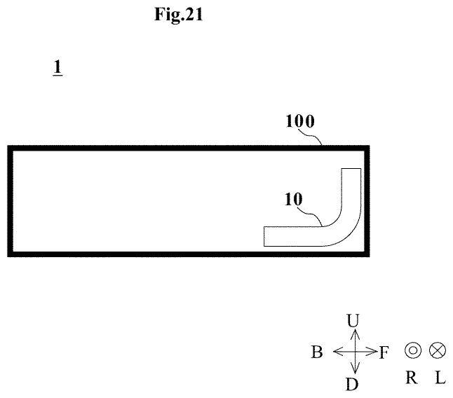

A structure of an electronic device 1 according to an example embodiment of the present invention will be described below with reference to the drawings. FIG. 21 is a sectional view of the electronic device 1 including the multilayer substrate 10.

The electronic device 1 includes the multilayer substrate 10 and a housing 100. The housing 100 includes the multilayer substrate 10. The electronic device 1 is a wireless communication terminal such as a smartphone, for example. The multilayer substrate 10 is bent.

### OTHER EXAMPLE EMBODIMENTS

The multilayer substrate according to the present invention is not limited to the multilayer substrates 10 and 10a to 10p, and can be modified within the scope of the present invention. The structures of the multilayer substrates 10 and 10a to 10p may be combined in any manner.

At least one of the materials of the insulator layer 16a (first insulator layer) and the insulator layer 16b (second insulator layer) may be, for example, liquid crystal polymer, polyimide, perfluoroalkoxyalkane, or polytetrafluoroethylene.

In the eleventh to thirteenth modifications, at least either one of the following may be satisfied: the area of the first conductor layer 22a is smaller than the area of the upper end portion (end portion on the positive side of the Z-axis) of the first through-hole h3a when viewed downward (in the negative direction of the Z-axis) or the area of the second conductor layer 25a is smaller than the area of the lower end portion (end portion on the negative side of the Z-axis) of the second through-hole h3b when viewed downward (in the negative direction of the Z-axis).

The first ground conductor layer 22 may be located on the upper main surface of the insulator layer 16a, or may be located above the upper main surface of the insulator layer 16a. In other words, the first ground conductor layer 22 does not have to be in contact with the upper main surface of the insulator layer 16a.

The third ground conductor layer 25 may be located on the lower main surface of the insulator layer 16b, or may be located below the lower main surface of the insulator layer 16b. In other words, the third ground conductor layer 25 does not have to be in contact with the lower main surface of the insulator layer 16b.

The space Sp1 may be located between the inner circumferential surface of the second through-hole h3b and the center CP of the first interlayer connection conductor v3a on the up-down axis (Z-axis).

The melting point of the material of the first interlayer connection conductors v1 to v4 may be higher than the melting point of the solder used to mount the electronic components. This makes it possible for the first interlayer connection conductors v1 to v4 not to melt when the electronic components are mounted. This reduces deformation of the first interlayer connection conductors v1 to v4. As a result, variations in the electrical characteristics of the multilayer substrate 10 are reduced.

In FIG. 4, the insulator layers 16b and 16c may be pressure-bonded before the insulator layers 16a to 16d are pressure-bonded.

The thickness of the insulator layer 16a on the up-down axis is smaller than the thickness of the insulator layer 16b on the up-down axis. However, the thickness of the insulator layer 16a on the up-down axis may be equal to or larger than the thickness of the insulator layer 16b on the up-down axis.

The thickness of the insulator layer 16d on the up-down axis is smaller than the thickness of the insulator layer 16c on the up-down axis. However, the thickness of the insulator layer 16d on the up-down axis may be equal to or larger than the thickness of the insulator layer 16c on the up-down axis.

The size relationship of the through-holes provided in the insulator layer 16a and the insulator layer 16b may be reversed.

An adhesive layer may be provided between the insulator layer 16b and the insulator layer 16c.

A portion of the first interlayer connection conductor v3a and a portion of the first interlayer connection conductor v4a may overlap each other when viewed downward. The first interlayer connection conductor v3a and the first interlayer connection conductor v4a do not have to overlap each other when viewed downward.

There may be air bubbles inside the first interlayer connection conductors v1 to v4. This makes it possible to achieve a reduction in weight of the multilayer substrates 10 and 10a to 10p.

The material of the protective layers 18a and 18b may be the same as the material of the insulator layers 16a to 16f.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A multilayer substrate comprising:
a multilayer body;
a first conductor layer;
a second conductor layer; and
a first interlayer connection conductor; wherein
the multilayer body includes a plurality of insulator layers including a first insulator layer and a second insulator layer laminated along a Z-axis;
the first conductor layer and the second conductor layer each include a positive main surface and a negative main surface;
the first insulator layer and the second insulator layer each include a positive main surface and a negative main surface;
the positive main surface of the second insulator layer is in contact with the negative main surface of the first insulator layer;
the first conductor layer is located on a positive side of the Z-axis relative to the first insulator layer;
the second conductor layer is located on a negative side of the Z-axis relative to the second insulator layer;
there is no other conductor layer between the negative main surface of the first conductor layer and the positive main surface of the second conductor layer;
the first insulator layer includes a first through-hole penetrating the first insulator layer along the Z-axis;
the second insulator layer includes a second through-hole penetrating the second insulator layer along the Z-axis;
the second through-hole overlaps the first through-hole when viewed downward;
when viewed in a positive direction of the Z-axis, an area of an end portion of the second through-hole on the positive side of the Z-axis is larger than an area of an end portion of the first through-hole on the negative side of the Z-axis;
the first interlayer connection conductor extends along the Z-axis inside the first through-hole and the second through-hole and electrically connects the first conductor layer and the second conductor layer; and
a space exists between a boundary of the first insulator layer and the second insulator layer and the first interlayer connection conductor.

2. The multilayer substrate according to claim 1, wherein the space faces at least a portion of an inner circumferential surface of the first through-hole and faces at least a portion of an inner circumferential surface of the second through-hole.

3. The multilayer substrate according to claim 1, wherein the space is between the inner circumferential surface of the first through-hole or the inner circumferential surface of the second through-hole and a center of the first interlayer connection conductor on the Z-axis.

4. The multilayer substrate according to claim 1, wherein, when viewed in the positive direction of the Z-axis, the end portion of the first through-hole on the negative side of the Z-axis fits into the end portion of the second through-hole on the positive side of the Z-axis.

5. The multilayer substrate according to claim 1, wherein
the first through-hole has a tapered shape that becomes narrower in the positive direction of the Z-axis; and
the second through-hole has a tapered shape that becomes narrower in a negative direction of the Z-axis.

6. The multilayer substrate according to claim 1, wherein
the first interlayer connection conductor includes a middle portion between an end portion of the first interlayer connection conductor on the positive side of the Z-axis and an end portion of the first interlayer connection conductor on the negative side of the Z-axis; and
the first interlayer connection conductor includes a first section with a tapered shape that becomes narrower from the end portion on the positive side of the Z-axis toward the middle portion, and a second section with a tapered shape that becomes narrower from the end portion on the negative side of the Z-axis toward the middle portion.

7. The multilayer substrate according to claim 6, wherein, when viewed in a negative direction of the Z-axis, at least a portion of a side surface of the first interlayer connection conductor in the first section, at least a portion of the side surface of the first interlayer connection conductor in the second section, and at least a portion of the space overlap each other.

8. The multilayer substrate according to claim 1, wherein, when viewed in a negative direction of the Z-axis, an area of the first conductor layer is smaller than an area of an end portion of the first through-hole on the positive side of the Z-axis, or when viewed in the negative direction of the Z-axis, an area of the second conductor layer is smaller than an area of an end portion of the second through-hole on the negative side of the Z-axis.

9. The multilayer substrate according to claim 1, wherein the first interlayer connection conductor includes an alloy including Sn.

10. The multilayer substrate according to claim 1, wherein a melting point of a material of the first interlayer connection conductor is equal to or lower than a melting point of solder used to mount an electronic component.

11. The multilayer substrate according to claim 1, wherein the first insulator layer and the second insulator layer include flexible resin.

12. The multilayer substrate according to claim 1, wherein a material of the first insulator layer is different from a material of the second insulator layer.

13. The multilayer substrate according to claim 1, wherein at least one of the first insulator layer and the second insulator layer includes liquid crystal polymer, polyimide, perfluoroalkoxyalkane, or polytetrafluoroethylene.

14. The multilayer substrate according to claim 1, wherein the first insulator layer and the second insulator layer are fused together.

15. The multilayer substrate according to claim 1, wherein
the multilayer body further includes a third insulator layer;
the third insulator layer includes a positive main surface and a negative main surface;
the negative main surface of the third insulator layer is in contact with the positive main surface of the first insulator layer; and
the first insulator layer includes an adhesive layer that bonds the second insulator layer and the third insulator layer.

16. The multilayer substrate according to claim 1, wherein a high-frequency signal having a frequency of equal to or higher than about 1 GHz and equal to or lower than about 1 THz is transmitted to the first conductor layer, the second conductor layer, and the first interlayer connection conductor, or a ground potential is connected to the first conductor layer, the second conductor layer, and the first interlayer connection conductor.

17. The multilayer substrate according to claim 1, further comprising:
a second interlayer connection conductor; wherein
the plurality of insulator layers include a third insulator layer;
the second interlayer connection conductor penetrates the third insulator layer along the Z-axis; and
no space exists between the second interlayer connection conductor and the third insulator layer.

18. The multilayer substrate according to claim 17, wherein
the multilayer body includes a positive main surface and a negative main surface; and
a distance from the first insulator layer to the positive main surface of the multilayer body is shorter than a distance from the third insulator layer to the positive main surface of the multilayer body.

19. The multilayer substrate according to claim 17, further comprising:
a first line section and a second line section aligned along an X-axis orthogonal to the Z-axis; wherein
the first insulator layer is located in the first line section and the second line section;
the third insulator layer is located in the first line section and not located in the second line section; and
a thickness of the first line section on the Z-axis is larger than a thickness of the second line section on the Z-axis.

20. An electronic device comprising the multilayer substrate according to claim 1.

21. A method for manufacturing a multilayer substrate, the method comprising:
preparing a first insulator layer and a second insulator layer, each including a positive main surface and a negative main surface aligned along a Z-axis;
forming a first through-hole penetrating the first insulator layer along the Z-axis;
forming a second through-hole penetrating the second insulator layer along the Z-axis; and
laminating the first insulator layer and the second insulator layer such that the negative main surface of the first insulator layer is in contact with the positive main surface of the second insulator layer, and forming a first interlayer connection conductor extending along the Z-axis inside the first through-hole and the second through-hole; wherein
when viewed in a positive direction of the Z-axis, an area of an end portion of the second through-hole on a positive side of the Z-axis is larger than an area of an end portion of the first through-hole on a negative side of the Z-axis;
a space exists between a boundary of the first insulator layer and the second insulator layer and the first interlayer connection conductor; and
the space faces at least a portion of an inner circumferential surface of the first through-hole and faces at least a portion of an inner circumferential surface of the second through-hole.
